(19) United States
(12) Patent Application Publication
(10) Pub. No.: US 2026/0036623 A1
(43) Pub. Date: Feb. 5, 2026

(54) FLIP-FLOPS FOR CIRCUIT TESTING BASED ON SCAN CHAINS

(71) Applicant: Texas Instruments Incorporated, Dallas, TX (US)

(72) Inventors: Pervez Garg, Bangalore (IN); Mudasir Shafat Kawoosa, Bangalore (IN); Piyushkumar Mansukhlal Chaniyara, Bangalore (IN)

(21) Appl. No.: 18/938,024

(22) Filed: Nov. 5, 2024

(30) Foreign Application Priority Data
Aug. 2, 2024 (IN) 202441058891
Aug. 2, 2024 (IN) 202441058892

(51) Int. Cl. G01R 31/3185

(52) U.S. Cl. CPC G01R 31/318536; G01R 31/318525

(57) ABSTRACT

An example device described herein includes first functional circuitry, second functional circuitry, and a shift register coupled to the first functional circuitry. The shift register of the example device includes a flip-flop, the flip-flop including a scan-in input coupled to the second functional circuitry, a scan-enable input, and an output. The example device also includes first test circuitry coupled to the scan-enable input and configured to cause the flip-flop to output a first value received by the flip-flop at the scan-in input from the second functional circuitry.

### CROSS-REFERENCE TO RELATED APPLICATIONS

This patent application claims the benefit of and priority to Indian Provisional Patent Application No. 202441058891, filed Aug. 2, 2024, and Indian Provisional Patent Application No. 202441058892, filed Aug. 2, 2024, which Applications are hereby incorporated herein by reference in their respective entireties.

### TECHNICAL FIELD

This description relates generally to circuit testing and, more particularly, to flip-flops for circuit testing based on scan chains.

### BACKGROUND

Design for testability (DFT) involves modifying the circuit design of a device to support testing of the device. One such DFT approach is scan testing in which the circuit design of the device is modified to include flip-flops arranged into scan chains. The scan chains enable an automatic test pattern generator (ATPG) to shift a test pattern into the device for the purpose of testing different circuit nodes of the device. During a scan test, the scan chain flip-flops control the circuit nodes under test using the test pattern and observe the resulting outputs of those circuit nodes. In some approaches, test point insertion (TPI) is used to improve controllability and observability in the circuit design. TPI approaches may involve the addition of dedicated test circuitry in the device to create test points that provide access to circuit nodes that would have otherwise been uncontrollable, unobservable or both uncontrollable and unobservable during a scan test of the device.

### SUMMARY

For methods and apparatus to provide flip-flops for circuit testing based on scan chains, an example device described herein includes first functional circuitry, second functional circuitry, and a shift register coupled to the first functional circuitry. The shift register of the example device includes a flip-flop including a scan-in input coupled to the second functional circuitry, a scan-enable input, and an output. The example device also includes first test circuitry coupled to the scan-enable input and configured to cause the flip-flop to output a first value received by the flip-flop at the scan-in input from the second functional circuitry.

For methods and apparatus to provide flip-flops for circuit testing based on scan chains, another example device described herein includes a flip-flop including a primary input, a scan-in input, and a scan-enable input. The example device also includes first functional circuitry coupled to the primary input of the flip-flop, first test circuitry coupled to the scan-in input of the flip-flop, second functional circuitry coupled to the first test circuitry, and second test circuitry coupled to the first test circuitry and coupled to the scan-enable input of the flip-flop. In the example device, the second test circuitry is configured to cause the first test circuitry to output a first value to the scan-in input of the flip-flop, with the first value received from the second functional circuit.

For methods and apparatus to provide flip-flops for circuit testing based on scan chains, yet another example device described herein includes a flip-flop including a primary input, a scan-in input, a scan-enable input, and an output. The example device also includes first functional circuitry coupled to the primary input of the flip-flop, and first test circuitry including a first data input, a control input, and an output. In the example device, the first data input of the first test circuitry is coupled to the output of the flip-flop. The example device further includes second functional circuitry coupled to the output of the first test circuitry, and second test circuitry coupled to the control input of the first test circuitry.

### BRIEF DESCRIPTION OF THE DRAWINGS

FIG. 1 is a block diagram of example device including a first circuit node to be observed and a second circuit node to be controlled during a scan test.

FIG. 2 is a block diagram of an example observe test point circuit including an additional flip-flop and logic circuitry to observe the first circuit node of FIG. 1 during a scan test.

FIG. 3 is a block diagram of a second example control test point circuit including an additional flip-flop and logic circuitry to control the second circuit node of FIG. 1 with a logic-1 value during a scan test.

FIG. 4 is a block diagram of a first example control test point circuit including an additional flip-flop and logic circuitry to control the second circuit node of FIG. 1 with a logic-0 value during a scan test.

FIG. 5 is a block diagram illustrating a first example circuit architecture that repurposes functional flip-flops of a device to implement observe and control test points for scan testing of a device.

FIG. 6 is a block diagram illustrating a second example circuit architecture that repurposes functional flip-flops of a device to implement observe and control test points for scan testing of a device.

FIG. 7 is a block diagram illustrating a third example circuit architecture that repurposes functional flip-flops of a device to implement observe and control test points for scan testing of a device.

FIG. 8 is a block diagram illustrating a fourth example circuit architecture to share a flip-flop used to implement an observe test point for scan testing of a device.

FIG. 9 is a block diagram illustrating a fifth example circuit architecture to share a flip-flop used to implement a control test point for scan testing of a device.

FIG. 10 illustrates an example procedure to select a functional flip-flop of a device to be repurposed for scan testing of the device.

FIG. 11 is a flowchart representative of example machine-readable instructions or example operations that may be at least one of executed, instantiated, or performed by example programmable circuitry to implement the example procedure of FIG. 10.

FIGS. 12-13 illustrate example performance results capable of being achieved by the mirror accelerator circuit(s) included in the example microcontroller unit of FIG. 2.

FIG. 14 is a block diagram of an example processing platform including programmable circuitry structured to execute, instantiate, or perform the example machine-readable instructions or perform the example operations of FIG. 11 to implement the procedure of FIG. 10.

FIG. 15 is a block diagram of an example software/firmware/instructions distribution platform (e.g., one or more servers) to distribute software, instructions, or firmware (e.g., corresponding to the example machine-readable instructions of FIG. 11) to client devices associated with end users or consumers (e.g., for license, sale, or use), retailers (e.g., for sale, re-sale, license, or sub-license), or original equipment manufacturers (OEMs) (e.g., for inclusion in products to be distributed to, for example, retailers or to other end users such as direct buy customers).

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Scan testing is one DFT approach for testing devices, such as system-on-chip (SoC) devices and other integrated circuits (ICs). An ongoing goal is to improve scan test coverage to meet target defect rates, such as for safety critical applications. For example, achieving a 99% or higher stuck-at coverage target has been challenging, especially for large gate count devices.

TPI for DFT can be used to improve scan test coverage by improving controllability and/or observability in the circuit design. TPI approaches may involve the addition of dedicated test circuitry, such as dedicated scan test flip-flops and other logic circuitry, to the device to create test points that provide access to circuit nodes that would have otherwise been uncontrollable and/or unobservable during a scan test of the device. However, for large gate count devices, such as devices with 5 million or more flip-flops, inclusion of just 1%-2% additional flip-flops for TPI can result in an additional 50,000 to 100,000 or more flip-flops being added to the circuit design, which can be a substantial DFT area overhead. Those additional TPI flip-flops can also contribute to routing congestion and an increased active/leakage power consumption of the device. Even for smaller circuit designs, any additional flip-flops added for TPI can increase circuit area and active/leakage power consumption.

In contrast, example TPI techniques described herein reduce or eliminate the use of dedicated scan test flip-flops while still achieving scan test coverage targets. Some example TPI techniques described herein employ circuit architectures that repurpose flip-flops of existing functional shift registers of the device to insert test points to control and/or observe circuit nodes during a scan test of the device. Some example TPI techniques described herein employ circuit architectures that repurpose functional shift registers or standalone, functional flip-flops of the device to insert test points to control and/or observe circuit nodes during a scan test of the device. Some example TPI techniques described herein employ a combination of repurposed functional shift registers and repurposed standalone, functional flip-flops to insert such test points in the circuit design of the device. Because the functional shift registers and standalone functional flip-flops are already present in the device to implement functionality of the device, repurposing these existing shift registers and/or standalone flip-flops for TPI avoids the additional circuit overhead and additional active/leakage power consumption associated with other scan testing approaches. Some example TPI techniques described herein also enable sharing of control and/or observe test points, further reducing the additional circuit overhead and additional active/leakage power consumption associated with scan testing.

Example TPI techniques based on flip-flop repurposing, as described herein, can lead to substantial DFT area overhead reduction while also reducing the amount of untestable circuit logic, resulting in improved device cost and test quality. Circuit architecture changes to repurpose flip-flops for TPI can also be validated with ATPG tools and simulations, and test vector generation can be fully automated using available ATPG tools. Thus, such example TPI techniques based on flip-flop repurposing can yield improvements in test quality and test time, while overcoming the shortcomings and concerns of area overhead, routing congestion, and power consumption, as compared to other DFT approaches.

As described in further detail below, example TPI techniques based on flip-flop repurposing can reduce or eliminate dedicated test-only flip-flops from a circuit design, while still providing the benefits of test points for improved scan coverage and pattern count reduction. Example TPI techniques based on flip-flop repurposing may be well-suited for area critical designs. Example TPI techniques based on flip-flop repurposing are also scalable and add little to no interference in the regular test architecture. As a result, example TPI techniques based on flip-flop repurposing, as described herein, can yield improved test quality for low defective part-per-million markets, along with reduced test times and reduced test costs.

Turning to the figures, a block diagram of an example device 100 including a first example circuit node 105 to be observed and a second example circuit node 110 to be controlled during a scan test is illustrated in FIG. 1. The device 100 can be any type of device, such as an SoC device, an IC, a semiconductor device, an optical device, a computer device, a memory device, etc. The circuit nodes 105 and 110 can be any numbers and/or types of circuits or circuitry, such as digital circuitry, analog circuitry, etc. In illustrated example of FIG. 1, the functional circuit design of the device 100 results in the first circuit node 105 being an unobservable circuit node that is not accessible for observation during a scan test of the device 100. In the illustrated example of FIG. 1, the functional circuit design of the device 100 results in the second circuit node 110 being an uncontrollable circuit node that is not accessible for control during a scan test of the device 100.

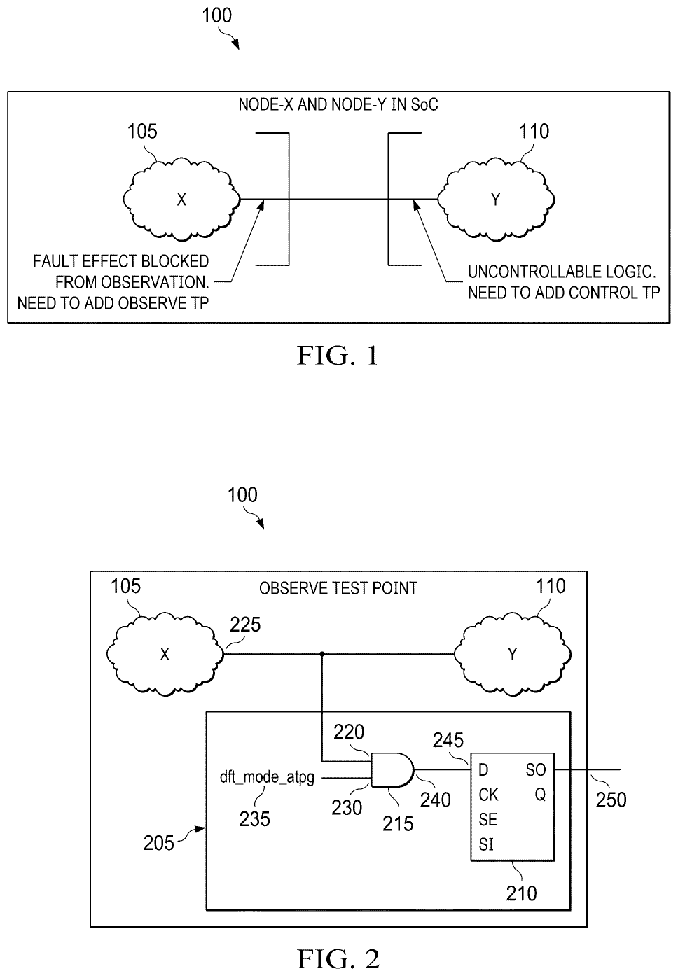

A block diagram of an example observe test point circuit 205 that can be included in the device 100 of FIG. 1 to observe the first circuit node 105 during a scan test is illustrated in FIG. 2. The observe test point circuit 205 includes an additional example flip-flop 210 and example logic circuitry 215. In some examples, the flip-flop 210 and the logic circuitry 215 may be added to the circuit design of the device 100 as part of the register transfer level (RTL) design and/or the synthesis of the device 100 for improved scan coverage and pattern count reduction. The logic circuitry 215 is implemented by an example AND gate 215 that has an input 220 coupled to an example output 225 of the circuit node 105 to permit the output 225 to be observed during a scan test. The AND gate 215 also another example input 230 that is driven by an example control signal 235 labeled “dft_mode_atpg” in the illustrated example. The value of the control signal 235 is set to a logic-1 value during a scan test of the device 100 to cause the value at the output 225 of the circuit node 105 to be observed at an example output 240 of the AND gate 215. In the illustrated example, the value of the control signal 235 is set to a logic-0 value during normal functional operation of the device 100 to cause the value at the output 225 of the circuit node 105 to be blocked from observation at the output 240 of the AND gate 215.

In the illustrated example of FIG. 2, the output 240 of the AND gate 215 is coupled to an example input 245 of the flip-flop 210. In the illustrated example, the flip-flop 210 is added to the device 100 to capture the value at the output 240 of the AND gate 215. For example, during a scan test of the device 100, the output 240 of the AND gate 215 corresponds to the observed output 225 of the circuit node 105. Thus, the flip-flop 210 is able to observe and capture the value of the observed output 225 of the circuit node 105 during the scan test of the device 100, thereby providing a test point as an example output of the flip-flop 210 at which to observe the circuit node 105. However, the additional flip-flop 210 is unused during normal functional operation of the device 100, thereby contributing to unused arca overhead, routing congestion, and power consumption during normal functional operation of the device 100.

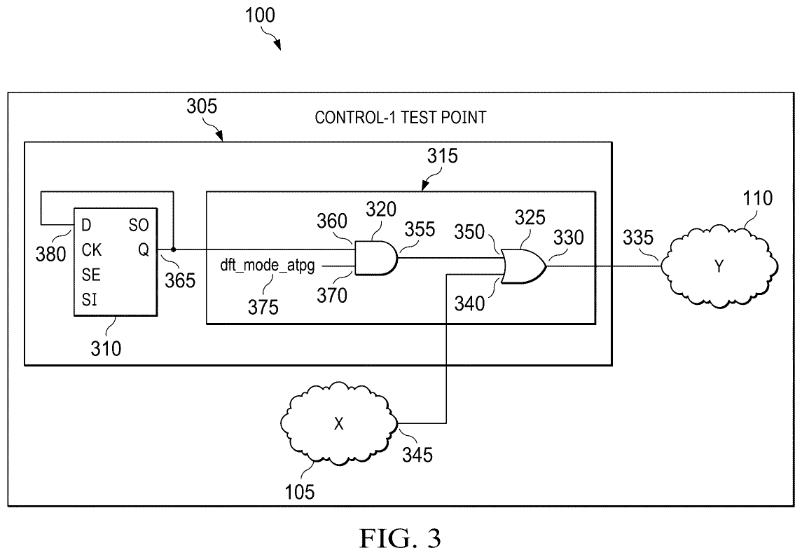

A block diagram of a first example control test point circuit 305 that can be included in the device 100 of FIG. 1 to control the second circuit node 110 with a logic-1 value during a scan test is illustrated in FIG. 3. The control test point circuit 305 includes an additional example flip-flop 310 and example logic circuitry 315. In some examples, the flip-flop 310 and the logic circuitry 315 may be added to the circuit design of the device 100 as part of the RTL design and/or the synthesis of the device 100 for improved scan coverage and pattern count reduction. The logic circuitry 315 is implemented by an example AND gate 320 and an example OR gate 325. The OR gate 325 has an example output 330 coupled to an example input 335 of the circuit node 110 to permit the input 335 to be controlled during a scan test. The OR gate 325 also has an example input 340 that is coupled to an example output 345 of the first circuit node 105, which couples the first circuit node 105 and the second circuit node 110 as in the example of FIG. 1 during normal functional operation of the device 100.

In the illustrated example of FIG. 3, the OR gate 325 has another example input 350 that is coupled to an example output 355 of the AND gate 320. The AND gate 320 has an example input 360 that is coupled to an example output 365 of the flip-flop 310. The AND gate also has another example input 370 that is driven by an example control signal 375 labeled “dft_mode_atpg” in the illustrated example. In the control test point circuit 305, the flip-flop 310 has a feedback structure in which the output 365 of the flip-flop 310 is coupled to an example primary input 380 of the flip-flop 310. During a scan test of the device 100, the flip-flop 310 is configured to output a logic-1 value at the output 365, and the control signal 375 is also set to a logic-1 value. Thus, the output 355 of the AND gate 320 is also a logic-1 value, which causes the output 330 of the OR gate 325 to also be a logic-1 value. As a result, a logic-1 value is applied to the input 335 of the circuit node 110, thereby controlling the circuit node 110 with a logic-1 value during the scan test.

During normal functional operation of the device 100, the control signal 375 is set to a logic-0 value, which causes the output 330 of the OR gate 325 to correspond to the value of the output 345 of the first circuit node 105. As a result, the first circuit node 105 is coupled to the input 335 of the circuit node 110 during normal functional operation of the device 100. However, the flip-flop 310 is unused during normal functional operation of the device 100, thereby contributing to unused area overhead, routing congestion, and power consumption during normal functional operation of the device 100.

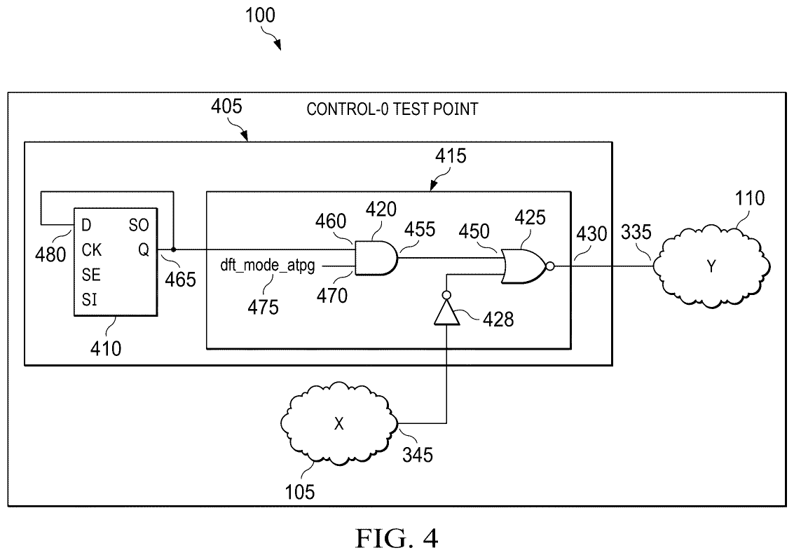

A block diagram of a second example control test point circuit 405 that can be included in the device 100 of FIG. 1 to control the second circuit node 110 with a logic-0 value during a scan test is illustrated in FIG. 4. The control test point circuit 405 includes an additional example flip-flop 410 and example logic circuitry 415. In some examples, the flip-flop 410 and the logic circuitry 415 may be added to the circuit design of the device 100 as part of the RTL design and/or the synthesis of the device 100 for improved scan coverage and pattern count reduction. The logic circuitry 415 is implemented by an example AND gate 420, an example NOR gate 425 and an example inverter 428. The NOR gate 425 has an example output 430 coupled to the example input 335 of the circuit node 110 to permit the input 335 to be controlled during a scan test. The NOR gate 425 also has an example input 440 that is coupled through the inverter 428 to the example output 345 of the first circuit node 105, which couples the first circuit node 105 and the second circuit node 110 as in the example of FIG. 1 during normal functional operation of the device 100.

In the illustrated example of FIG. 4, the NOR gate 425 has another example input 450 that is coupled to an example output 455 of the AND gate 420. The AND gate 420 has an example input 460 that is coupled to an example output 465 of the flip-flop 410. The AND gate also has another example input 470 that is driven by an example control signal 475 labeled “dft_mode_atpg” in the illustrated example. In the control test point circuit 405, the flip-flop 410 has a feedback structure in which the output 465 of the flip-flop 410 is coupled to an example primary input 480 of the flip-flop 410. During a scan test of the device 100, the flip-flop 410 is configured to output a logic-1 value at the output 465, and the control signal 475 is also set to a logic-1 value. Thus, the output 455 of the AND gate 420 is also a logic-1 value, which causes the output 430 of the NOR gate 425 to be a logic-0 value. As a result, a logic-0 value is applied to the input 335 of the circuit node 110, thereby controlling the circuit node 110 with a logic-0 value during the scan test.

During normal functional operation of the device 100, the control signal 475 is set to a logic-0 value, which causes the output 430 of the NOR gate 425 to correspond to the value of the output 345 of the first circuit node 105. As a result, the first circuit node 105 is coupled to the input 335 of the circuit node 110 during normal functional operation of the device 100. However, the flip-flop 410 is unused during normal functional operation of the device 100, thereby contributing to unused area overhead, routing congestion, and power consumption during normal functional operation of the device 100.

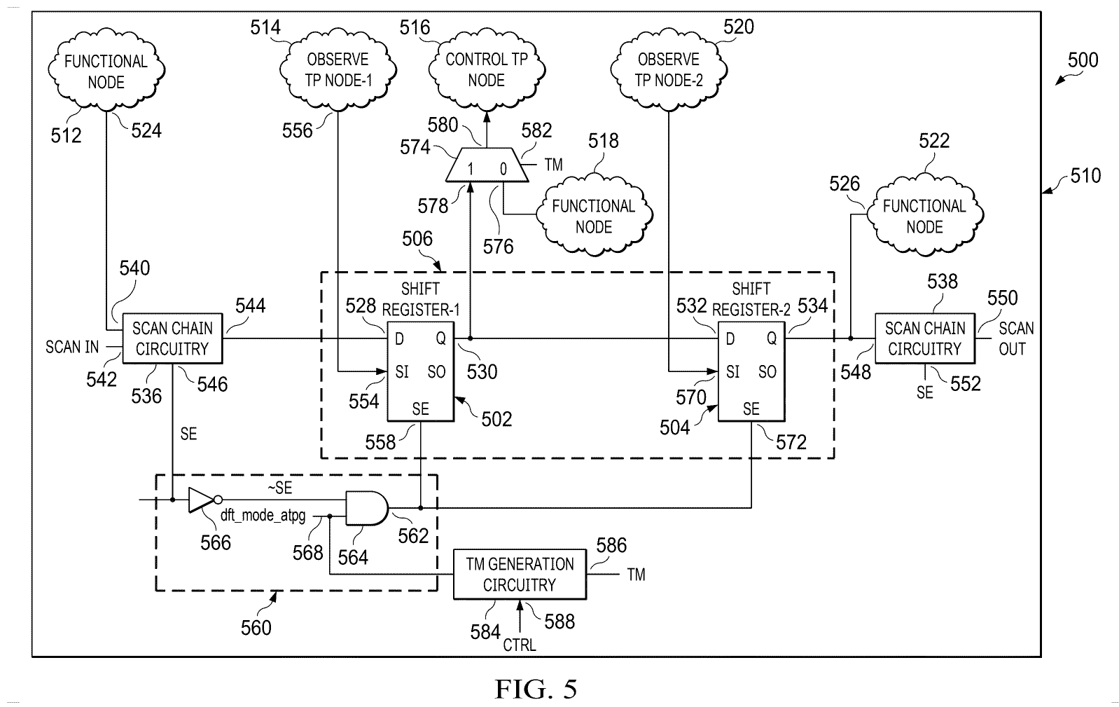

A block diagram illustrating a first example circuit architecture 500 that repurposes example functional flip-flops 502 and 504 included in an example shift register 506 of an example device 510 to implement observe and control test points for scan testing of the device 510 is illustrated in FIG. 5. The device 510 can be any type of device, such as an SoC device, an IC, a semiconductor device, an optical device, a compute device, a memory device, etc. In the illustrated example of FIG. 5, the device 510 includes example functional circuit nodes 512, 514, 516, 518, 520 and 522 configured to implement functionality in the device 510. The functional circuit nodes 512, 514, 516, 518, 520 and 522 can be any numbers and/or types of circuits or circuitry, such as digital circuitry, analog circuitry, circuit blocks, intellectual property (IP) blocks, accelerators, etc. For example, the functional circuit nodes 512, 514, 516, 518, 520 and 522 can range from discrete digital logic gates to more complete circuitry, such as one or more memories, microcontrollers, central processing units (CPUs), graphics processing units (GPUs), etc.

In the illustrated example of FIG. 5, the shift register 506 is also included in the device 510 to implement functionality in the device 510. For example, the shift register 506 is configured in the device 510 to couple the functional circuit node 512 to the functional circuit node 522 such that a value at an output 524 of the functional circuit node 512 can be shifted through the shift register 506 to an input 526 of the functional circuit node 522.

As shown in FIG. 5, the shift register 506 includes the flip-flops 502 and 504. The flip-flop 502 has a primary input 528 and a primary output 530. Likewise, the flip-flop 504 has a primary input 532 and a primary output 534. To implement the shift register 506, the flip-flops 502 and 504 are configured such that the primary output 530 of the flip-flop 502 is coupled to the primary input 532 of the flip-flop 504. As such, during normal functional operation of the device 510, a value of the primary input 528 of the flip-flop 502 is shifted to the primary output 530 of the flip-flop 502 during a first clock cycle/period. Then, during a subsequent second clock cycle/period, the value is shifted from the primary output 530 of the flip-flop 502 (which is coupled to the primary input 532 of the flip-flop 504) to the primary output 534 of the flip-flop 504. Although the shift register 506 includes two flip-flops in the illustrated example, the shift register 506 can include any number of flip-flops.

The device 510 of the illustrated example also includes example scan chain circuitry 536 and 538 to permit scan testing of the device 510. In the first circuit architecture 500, the scan chain circuitry 536 and the scan chain circuitry 538 are coupled to the shift register 506 to implement a scan chain to support scan testing of the device 510. More specifically, in the illustrated example, the scan chain circuitry 536 has an input 540 that is coupled to the output 524 of the functional circuit node 512. The scan chain circuitry 536 also has another input 542 (labeled “SCAN IN” in FIG. 5) that is configured to accept a test pattern from an ATPG during scan testing of the device 510. The scan chain circuitry 536 further has an output 544 that is coupled to the input 528 of the flip-flop 502 of the shift register 506. During normal functional operation of the device 510, the scan chain circuitry 536 is configured to couple the output 524 of the functional circuit node 512 to the output 544 of the scan chain circuitry 536, which causes the output 524 of the functional circuit node 512 to be coupled to the input 528 of the flip-flop 502 of the shift register 506.

However, to support scan testing of the device 510, the scan chain circuitry 536 has a scan-enable (SE) input 546 that can be controlled to cause the SCAN IN input 542 of the scan chain circuitry 536 to be coupled to the output 544 of the scan chain circuitry 536 and, thus, to the input 528 of the flip-flop 502 of the shift register 506. For example, when the SE input 546 is set to a first value, such as a logic-1 value, the scan chain circuitry 536 couples the SCAN IN input 542 of the scan chain circuitry 536 to the output 544 of the scan chain circuitry 536. However, when the SE input 546 is set to a second value, such as a logic-0 value, the scan chain circuitry 536 couples the input 540 of the scan chain circuitry 536 to the output 544 of the scan chain circuitry 536. Thus, during a scan test, an ATPG can set the SE input 546 to the first value (e.g., logic-1 value) and apply a test pattern to the input 540 of the scan chain circuitry 536 to cause the test pattern to be shifted into the shift register 506 for the purpose of scan testing the device 510.

The scan chain circuitry 538 is included in the device 510 to capture an output pattern generated during the scan test in response to the test pattern applied to the input 542 of the scan chain circuitry 536 (e.g., by an ATPG). For example, the scan chain circuitry 538 has an input 548 that is coupled to the output 534 of the flip-flop 504. The scan chain circuitry 538 also has an output 550 (labeled “SCAN OUT” in FIG. 5) to provide the output pattern generated during the scan test in response to the test pattern applied to the input 542 of the scan chain circuitry 536. The scan chain circuitry 538 further has an SE input 552 to control whether the output 550 of the scan chain circuitry 538 is enabled (e.g., active). For example, when the SE input 552 is set to a second value, such as a logic-0 value, the scan chain circuitry 538 couples the input 548 of the scan chain circuitry 538 to the SCAN OUT output 550 of the scan chain circuitry 538. However, when the SE input 552 is set to a first value, such as a logic-1 value, the scan chain circuitry 538 decouples, or otherwise blocks, the input 548 of the scan chain circuitry 538 from the SCAN OUT output 550 of the scan chain circuitry 538. Thus, during a scan test, an ATPG can set the SE input 552 to the second value (e.g., logic-0 value) to cause the resulting output pattern generated during the scan test of the device 510 to be shifted out of the SCAN OUT output 550.

In the illustrated example of FIG. 5, the functional circuit nodes 514 and 520 are to be observed during a scan test of the device 510, and the functional circuit node 516 is to be controlled during the scan test of the device 510. To support such scan testing, the first circuit architecture 500 repurposes the flip-flop 502 to implement an observe TP for the functional circuit node 514, repurposes the flip-flop 504 to implement an observe TP for the functional circuit node 520, and repurposes the flip-flop 502 to implement a control TP for the functional circuit node 516. More specifically, a scan test of the device 510 is divided into alternating shift periods and capture periods. During a shift period, an ATPG shifts a next value of a test pattern into SCAN IN input 542 of the scan chain circuitry 536 (e.g., by setting the SE input 546 to a first value, such as a logic-1 value). During a capture period, the ATPG captures a next value of resulting output pattern from the SCAN OUT output 550 of the scan chain circuitry 538. Thus, in the first circuit architecture 500, the flip-flop 502 is repurposed to implement the observe TP for the functional circuit node 514 during a capture period of the scan test, the flip-flop 504 is repurposed to implement the observe TP for the functional circuit node 520 during a capture period of the scan test, and the flip-flop 502 is repurposed to implement the control TP for the functional circuit node 516 during the shift period of a scan test.

In the illustrated example, the flip-flop 502 is repurposed to implement the observe TP for the functional circuit node 514 as follows. The flip-flop 502 has a scan-in (SI) input 554 that is coupled to the functional circuit node 516 (e.g., to an output 556 of the functional circuit node 516). The flip-flop 502 also has an SE input 558 that is coupled to first example test circuitry 560 (e.g., to an output 562 of the first test circuitry 560) included in the device 510. The flip-flop 502 is configured such that a first value, such as a logic-1 value, applied to the SE input 558 causes the SI input 554 to be coupled to the primary output 530 of the flip-flop 502, and a second value, such as a logic-0 value, applied to the SE input 558 causes the primary input 528 to be coupled to the primary output 530 of the flip-flop 502.

With the foregoing operation in mind, the first test circuitry 560 is configured to cause the flip-flop 502 to output a first value received by the flip-flop 502 at the SI input 554 from the functional circuit node 514 during a capture period of a scan test of the device 510, thereby implementing an observe TP for the functional circuit node 514. Also, the first test circuitry 560 is configured to cause the flip-flop 502 to output a second value received by the flip-flop 502 at the primary input 528 from the scan chain circuitry 536 during a shift period of the scan test of the device 510, thereby implementing scan chain functionality to permit the test pattern to be shifted into the device 510 during the shift periods of the scan test. For example, the first test circuitry 560 is configured to output a first logic value (e.g., a logic-1 value) to the SE input 558 to define the capture period of the scan test, and to output a second logic value (e.g., a logic-0 value) to the SE input 558 to define the shift period of the scan test. In this way, the first test circuitry 560 causes the SI input 554 (and, thus, the functional circuit node 514) to be coupled to the output 530 of the flip-flop 502 during capture periods of the scan test, and causes the primary input 528 (and, thus, the scan chain circuitry 536) to be coupled to the output 530 of the flip-flop 502 during shift periods of the scan test.

In the illustrated example, to implement such operation, the first test circuitry 560 includes an example AND gate 564 and an example inverter 566. In the illustrated example, the inverter 566 inverts the logic value applied by the ATPG to the SE input 546 of the scan chain circuitry 536. For example, the ATPG applies a first value, such as a logic-1 value, to the SE input 546 to define a shift period of the scan test, and applies a second value, such as a logic-0 value, to the SE input 546 to define a capture period of the scan test. The AND gate 564 accepts as input the inverted value of the SE input 546 and an example control signal 568 labeled “dft_mode_atpg” in the illustrated example. The value of the control signal 235 is set to a logic-1 value during a scan test of the device 510, and is set to a logic-0 value during normal operation of the device 510. Thus, during a scan test of the device 510, the output 562 of the first test circuitry 560 provides the first logic value (e.g., a logic-1 value) to the SE input 558 to define the capture periods of the scan test, and provides the second logic value (e.g., a logic-0 value) to the SE input 558 to define the shift periods of the scan test. During normal operation, the output 562 of the first test circuitry 560 is set to the second logic value (e.g., a logic-0 value), thereby causing primary input 528 to be coupled to the primary output 530 of the flip-flop 502.

In the illustrated example of FIG. 5, the flip-flop 504 and the first test circuitry 560 are coupled and configured in a similar manner to implement the observe TP for the functional circuit node 520. For example, the flip-flop 504 has an SI input 570 that is coupled to the functional circuit node 520. The flip-flop 504 also has an SE input 572 that is coupled to the output 562 of the first example test circuitry 560. As discussed above, the first test circuitry 560 is configured to cause the flip-flop 504 to output a first value received by the flip-flop 504 at the SI input 570 from the functional circuit node 520 during a capture period of a scan test of the device 510, thereby implementing an observe TP for the functional circuit node 520. Also, the first test circuitry 560 is configured to cause the flip-flop 504 to output a second value received by the flip-flop 504 at its primary input 532 during a shift period of the scan test of the device 510, thereby implementing scan chain functionality to permit the test pattern to be shifted into the device 510 during the shift periods of the scan test. For example, and as described above, the first test circuitry 560 is configured to output a first logic value (e.g., a logic-1 value) to the SE input 572 to define the capture period of the scan test, and to output a second logic value (e.g., a logic-0 value) to the SE input 572 to define the shift period of the scan test. In this way, the first test circuitry 560 causes the SI input 570 (and, thus, the functional circuit node 520) to be coupled to the output 534 of the flip-flop 504 during capture periods of the scan test, and causes the primary input 532 (and, thus, the scan chain circuitry 536 by way of the flip-flop 502) to be coupled to the output 534 of the flip-flop 504 during shift periods of the scan test.

In the illustrated example of FIG. 5, the flip-flop 502 is repurposed to implement the control TP for the functional circuit node 516 as follows. During normal operation of the device 510, the functional circuit node 516 is coupled to and receives input from the functional circuit node 518. However, during a scan test, the functional circuit node 516 is to be controlled by the output 530 of the flip-flop 502 based on a test pattern provided at the input 528 of the flip-flop 502. Thus, in the first circuit architecture 500, the device 510 includes second example test circuitry 574 configured to couple either the functional circuit node 518 or the output 530 of the flip-flop 502 to the functional circuit node 516 depending whether the device 510 is under normal operation or a scan test.

For example, the second test circuitry 574 can be implemented by a multiplexer or similar circuit. In the illustrated example, the second test circuitry 574 has an input 576 coupled to the functional circuit node 518, an input 578 coupled to the output 530 of the flip-flop 502, and an output 580 coupled to the functional circuit node 516. The second test circuitry 574 also has a control input 582. The second test circuitry 574 is configured such that a first value, such as a logic-1 value, applied to the control input 582 causes the input 578 to be coupled to the output 580, thereby causing the output 530 of the flip-flop 502 to be coupled to the functional circuit node 516. However, a second value, such as a logic-0 value, applied to the control input 582 causes the input 576 to be coupled to the output 580, thereby causing the functional circuit node 518 to be coupled to the functional circuit node 516.

In the illustrated example first circuit architecture 500, the device 510 also includes third test circuitry 584 to set the value of the control input 582 of the second test circuitry 574 to control whether the functional circuit node 518 or the output 530 of the flip-flop 502 is coupled to the functional circuit node 516. For example, the third test circuitry 584 is configured to generate an output control signal 586 based on the control signal 568 and another control signal 588. In some examples, the third test circuitry 584 can be configured to generate the output control signal 586 to have a first value, such as a logic-1 value, during a shift period of a scan test to cause a value of a test pattern provided at the output 530 of the flip-flop 502 to be routed to the functional circuit node 516 to control the functional circuit node 516. In some such examples, the third test circuitry 584 can be configured to generate the output control signal 586 to have a second value, such as a logic-0 value, otherwise to cause the functional circuit node 516 to be coupled to the functional circuit node 516.

Thus, in the illustrated example first circuit architecture 500, multiple circuit nodes can be observed and/or controlled from a single shift register flip-flop, which can eliminate the need for adding dedicated DFT-only control and observe flip-flops in design. For example, in the device 510, the first test circuitry 560 is configured to cause the flip-flop 502 to output, during a capture period of a scan test, an observed value received by the flip-flop's SI input 554 from the functional circuit node 514, thereby implementing an observe TP for the functional circuit node 514 during the capture period of the scan test. However, during a shift period of the scan test, first test circuitry 560 causes the flip-flop 502 to output a test pattern value received by the flip-flop's primary input 528, and the second test circuitry 574 receives that test pattern value from the flip-flop 502, and outputs the test pattern value to the functional circuit node 516, thereby implementing a control TP for the functional circuit node 516. In this way, the same flip-flop 502 can implement multiple TPs for multiple different circuit nodes to be tested during a scan test.

In some examples, a shift register may not be present in the circuit architecture. The following figures illustrate alternate arrangements that can be implemented without a shift register. The alternate arrangements can use (e.g., repurpose) functional flip-flops as test points.

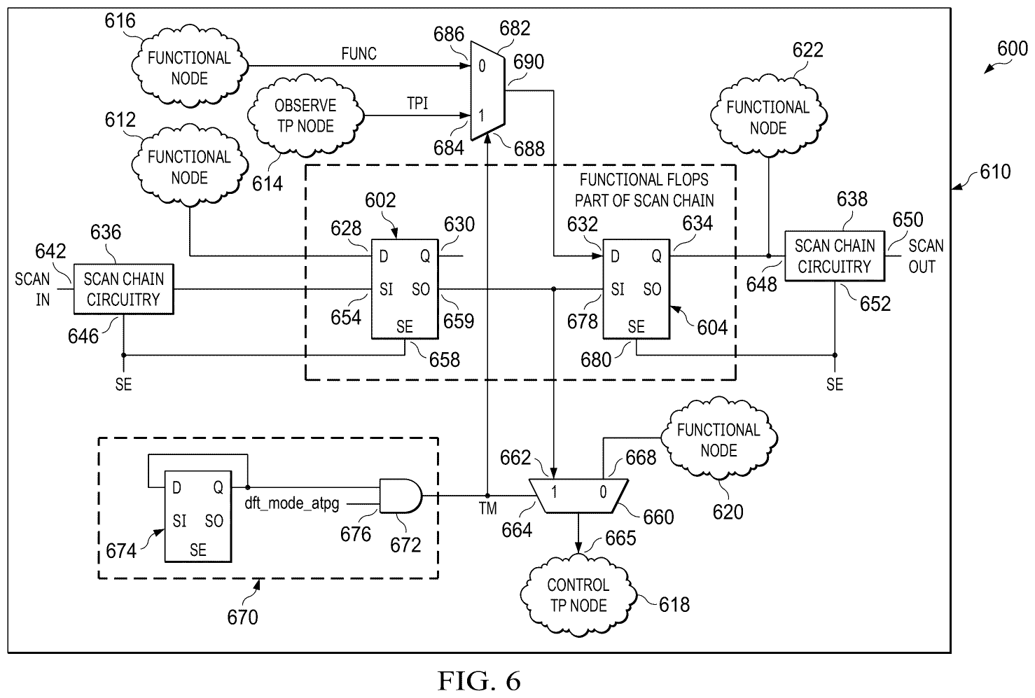

A block diagram illustrating a second example circuit architecture 600 that repurposes example functional flip-flops 602 and 604 of an example device 610 to implement observe and control test points for scan testing of the device 610 is illustrated in FIG. 6. The device 610 can be any type of device, such as an SoC device, an IC, a semiconductor device, an optical device, a compute device, a memory device, etc. In the illustrated example of FIG. 6, the device 610 includes example functional circuit nodes 612, 614, 616, 618, 620 and 622 configured to implement functionality in the device 610. The functional circuit nodes 612, 614, 616, 618, 620 and 622 can be any numbers and/or types of circuits or circuitry, such as digital circuitry, analog circuitry, circuit blocks, IP blocks, accelerators, etc. For example, the functional circuit nodes 612, 614, 616, 618, 620 and 622 can range from discrete digital logic gates to more complete circuitry, such as one or more memories, microcontrollers, CPUs, GPUs, etc.

In the illustrated example of FIG. 6, the flip-flops 602 and 604 are also included in the device 610 to implement functionality in the device 610. For example, the flip-flop 602 has a primary input 628 and a primary output 630, and the flip-flop 604 has a primary input 632 and a primary output 634. In the illustrated example, the functional circuit node 612 is coupled to the primary input 628 of the flip-flop 602 to latch an output of the functional circuit node 612 during normal operation. Also, during normal operation of the device 610, the flip-flop 604 couples the functional circuit node 616 to the functional circuit node 622.

Furthermore, the flip-flops 602 and 604 are included in a scan chain implemented with example scan chain circuitry 636 and 638. The scan chain circuitry 636 has an input 642 (labeled “SCAN IN” in FIG. 6) that is configured to accept a test pattern from an ATPG during scan testing of the device 610. The scan chain circuitry 636 also has an SE input 646 that can be controlled as described above to cause the test pattern applied at the input 642 to be provided to an SI input 654 of the flip-flop 602. In the illustrated example, the flip-flops 602 and 604 are coupled together as shown to allow the test pattern to be shifted into the device 610 during the scan test. The scan chain circuitry 638 is included in the device 610 to capture an output pattern generated during the scan test in response to the test pattern applied to the input 642 of the scan chain circuitry 636 (e.g., by an ATPG). For example, the scan chain circuitry 638 has an input 648 that is coupled to the output 634 of the flip-flop 604. The scan chain circuitry 638 also has an output 650 (labeled “SCAN OUT” in FIG. 6) to provide the output pattern generated during the scan test in response to the test pattern applied to the input 642 of the scan chain circuitry 636. The scan chain circuitry 638 further has an SE input 652 to control whether the output 650 of the scan chain circuitry 638 is enabled (e.g., active), as described above.

In the illustrated example of FIG. 6, the functional circuit node 614 is to be observed during a scan test of the device 610, and the functional circuit node 618 is to be controlled during the scan test of the device 610. To support such scan testing, the second circuit architecture 600 repurposes the flip-flop 604 to implement an observe TP for the functional circuit node 614, and repurposes the flip-flop 602 to implement a control TP for the functional circuit node 618. More specifically, in the second circuit architecture 600, the flip-flop 604 is repurposed to implement the observe TP for the functional circuit node 614 during a capture period of the scan test, and the flip-flop 602 is repurposed to implement the control TP for the functional circuit node 608 during the shift period of a scan test.

In the illustrated example second circuit architecture 600, the flip-flop 602 is repurposed to implement the control TP for the functional circuit node 618 as follows. As described above, the primary input 628 of the flip-flop 602 is coupled to the functional circuit node 612, and the SI input 654 of the flip-flop 602 is coupled to the scan chain circuitry 636. The flip-flop 602 also has an SE input 658 coupled to the SE input 652 of the scan chain circuitry 636. Thus, when the SE input 652 of the scan chain circuitry 636 is set to a first value, such as a logic-1 value, the SE input 658 of the flip-flop 602 is also set to the first value, such as the logic-1 value, which causes the value of the test pattern at the SCAN IN input 642 to be routed to the primary output 630 and a scan-out output 659 of the flip-flop 602.

In the illustrated example second circuit architecture 600, the device 610 also includes first example test circuitry 660 that has a first data input 662, a control input 664, and an output 665. For example, the first test circuitry 660 can be implemented by a multiplexer or similar circuit. In the illustrated example, the first data input 662 of the first test circuitry 660 is coupled to the SO output 659 of the flip-flop 602, and the functional circuit node 618 is coupled to the output 665 of the first test circuitry 660. The first test circuitry 660 also includes a second data input 668 that is coupled with the functional circuit node 620. The first test circuitry 660 is configured to couple either the data input 662 or the data input 668 to the output 665 based on the control input 664 of the first test circuitry 660. For example, the control input 664 can be set to a second value, such as a logic-0 value, to cause the data input 668 and, thus, the functional circuit node 620 to be coupled to the functional circuit node 618 during normal operation of the device 610. However, the control input 664 can be set to a first value, such as a logic-1 value, to cause the data input 662 and, thus, the SO output 659 to be coupled to the functional circuit node 618 during a scan test of the device 610.

In the illustrated example second circuit architecture 600, the device 610 further includes second example test circuitry 670 coupled to the control input 664 of the first test circuitry 660. The second test circuitry 670 causes the first test circuitry 660 to couple the output 659 of the flip-flop 602 to the functional circuit node 618 when a scan test is enabled. However, the second test circuitry 670 causes the first test circuitry 660 to couple the functional circuit node 620 to the functional circuit node 618 when the scan test is disabled (e.g., during normal operation of the device 610).

In the illustrated example, to implement such operation, the second test circuitry 670 includes an example AND gate 672 and an example flip-flop 674. The AND gate 672 accepts as input an example control signal 676 labeled “dft_mode_atpg” in the illustrated example. The value of the control signal 676 is set to a logic-1 value during a scan test of the device 610, and is set to a logic-0 value during normal operation of the device 610. The flip-flop 674 is arranged in a feedback configuration and can be configured to output a logic-1 value or a logic-0 value during a scan test of the device 610. For example, if the flip-flop 674 is configured to output a logic-1 value during a scan test, the second test circuitry 670 outputs a logic-1 value during the scan test (because the control signal 676 is set to a logic-1 value), which causes the first test circuitry 660 to couple the output 659 of the flip-flop 602 to the functional circuit node 618. However, during normal operation, the control signal 676 is set to a logic-0 value, which causes the first test circuitry 660 to output a logic-0 value, which causes the first test circuitry 660 to couple the functional circuit node 620 to the functional circuit node 618.

In the illustrated example second circuit architecture 600, the flip-flop 604 is repurposed to implement the observation TP for the functional circuit node 614 as follows. As described above, the flip-flop 604 has a primary input 632 and a primary output 634. The flip-flop 604 also has a scan-in input 678 and a scan-enable input 680. As described above, during normal operation of the device 610, the flip-flop 604 couples the functional circuit node 616 to the functional circuit node 622. However, during a scan test, the flip-flop 604 is to be repurposed and coupled to the functional circuit node 614 to implement the observation TP for the functional circuit node 614.

Thus, in the second circuit architecture 600, the device 610 includes third example test circuitry 682 that has a first data input 684, a second data input 686, a control input 688, and an output 690. For example, the third test circuitry 682 can be implemented by a multiplexer or similar circuit. In the illustrated example, the output 690 of the third test circuitry 682 is coupled to the primary input 632 of the flip-flop 604, the functional circuit node 614 is coupled to the first data input 684 of the third test circuitry 682, and the functional circuit node 616 coupled to the second data input 686 of the third test circuitry 682. Also, the second test circuitry 670 is coupled to the control input 688 of the third test circuitry 682.

As described above, the second test circuitry 670 can be configured to output a logic-1 value during a scan test (e.g., when a scan test is enabled) and to output a logic-0 value during normal operation (e.g., when the scan test is disabled). Thus, the second test circuitry 670 can be configured to cause the third test circuitry 682 to couple the functional circuit node 614 to the primary input 632 of the flip-flop 604 when a scan test is enabled, thereby implementing an observe TP for the functional circuit node 614. The second test circuitry 670 can also be configured to couple the functional circuit node 616 to the primary input 632 of the flip-flop 604 when the scan test is disabled (e.g., during normal operation).

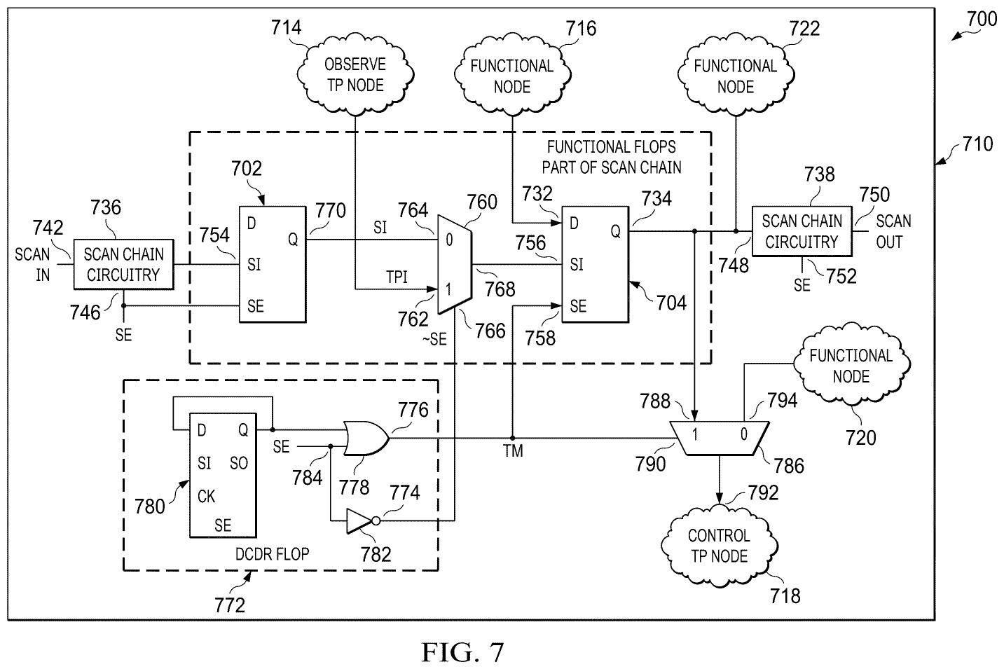

A block diagram illustrating a third example circuit architecture 700 that repurposes an example functional flip-flops 702 and 704 of an example device 710 to implement observe and control test points for scan testing of the device 710 is illustrated in FIG. 7. In the second circuit architecture 600 of FIG. 6., the third test circuitry 682 is interposed between the functional circuit node 616 and the functional circuit node 622, which can add a timing delay between the functional circuit node 616 and the functional circuit node 622 during normal operation of the device 610. Thus, the second circuit architecture 600 may be appropriate is there is sufficient timing slack on the path between the functional circuit node 616 and the functional circuit node 622. In such cases, the third test circuitry 682 can be coupled between the functional circuit nodes 616 and 622 because of the timing slack along the functional path between nodes 616 and 622.

However, if there is not sufficient timing slack, the third circuit architecture 700 provides a different approach for flip-flop repurposing that adds an observe TP without interposing circuitry in the functional path of the flip-flop being repurposed. That is, the timing slack along the functional path between the functional circuit nodes 716 and 722 may not be sufficient to insert test circuitry. Instead, the third circuit architecture 700, the observe TP is implemented with the SI path of existing flip-flop being repurposed, as described in further detail below. The arrangement of the third circuit architecture 700 may have little or no impact on the timing of the functional data path between functional circuit nodes 716 and 722.

The device 710 can be any type of device, such as an SoC device, an IC, a semiconductor device, an optical device, a compute device, a memory device, etc. In the illustrated example of FIG. 7, the device 710 includes example functional circuit nodes 714, 716, 718, 720 and 722 configured to implement functionality in the device 710. The functional circuit nodes 714, 716, 718, 720 and 722 can be any numbers and/or types of circuits or circuitry, such as digital circuitry, analog circuitry, circuit blocks, IP blocks, accelerators, etc. For example, the functional circuit nodes 714, 716, 718, 720 and 722 can range from discrete digital logic gates to more complete circuitry, such as one or more memories, microcontrollers, CPUs, GPUs, etc.

In the illustrated example of FIG. 7, the flip-flops 702 and 704 are also included in the device 710 to implement functionality in the device 710. For example, the flip-flop 704 has a primary input 732 and a primary output 734. In the illustrated example, during normal operation of the device 710, the flip-flop 704 couples the functional circuit node 716 to the functional circuit node 722.

Furthermore, the flip-flops 702 and 704 are included in a scan chain implemented with example scan chain circuitry 736 and 738. The scan chain circuitry 736 has an input 742 (labeled “SCAN IN” in FIG. 7) that is configured to accept a test pattern from an ATPG during scan testing of the device 710. The scan chain circuitry 736 also has an SE input 746 that can be controlled as described above to cause the test pattern applied at the input 742 to be provided to an SI input 754 of the flip-flop 702. In the illustrated example, the flip-flops 702 and 704 are coupled together as shown to allow the test pattern to be shifted into the device 710 during the scan test. The scan chain circuitry 738 is included in the device 710 to capture an output pattern generated during the scan test in response to the test pattern applied to the input 742 of the scan chain circuitry 736 (e.g., by an ATPG). For example, the scan chain circuitry 738 has an input 748 that is coupled to the output 734 of the flip-flop 704. The scan chain circuitry 738 also has an output 750 (labeled “SCAN OUT” in FIG. 7) to provide the output pattern generated during the scan test in response to the test pattern applied to the input 742 of the scan chain circuitry 736. The scan chain circuitry 738 further has an SE input 752 to control whether the output 750 of the scan chain circuitry 738 is enabled (e.g., active), as described above.

In the illustrated example of FIG. 7, the functional circuit node 714 is to be observed during a scan test of the device 710, and the functional circuit node 718 is to be controlled during the scan test of the device 710. To support such scan testing, the third circuit architecture 700 repurposes the flip-flop 704 to implement an observe TP for the functional circuit node 714 during a capture period of a scan test, and repurposes the same flip-flop 704 to implement a control TP for the functional circuit node 718 during a shift period of the scan test.

In the illustrated example third circuit architecture 700, the flip-flop 704 is repurposed to implement the observe TP for the functional circuit node 714 as follows. As described above, the flip-flop 704 has a primary input 732 and a primary output 734, with the functional circuit node 716 coupled to the primary input 732 of the flip-flop 704. The flip-flop 704 also has an SI input 756 and an SE input 758. In the third circuit architecture 700, the device 710 also includes first example test circuitry 760 having a first data input 762, a second data input 764, a control input 766 and an output 768. In the illustrated example, the output 768 of the first test circuitry 760 is coupled to the SI input 756 of the flip-flop 704, the functional circuit node 714 coupled to the first data input 762 of the first test circuitry 760, and an output 770 of the flip-flop 702 is coupled to the second data input 764 of the first test circuitry 760. In the third circuit architecture 700, the device 710 further includes second example test circuitry 772 that has a first output 774 coupled to the control input 766 of the first test circuitry 760 and a second output 776 coupled to the SE input 758 of the flip-flop 704. As described in further detail below, the second test circuitry 772 is configured to cause the first test circuitry 760 to output an observed value received from the functional circuit node 714 to the SI input 756 of the flip-flop 704 during the capture period of a scan test.

For example, the first test circuitry 760 can be implemented by a multiplexer or similar circuit. The first test circuitry 660 is configured to couple either the first data input 762 or the second input 764 to the output 768 based on the control input 766 of the first test circuitry 760. For example, the control input 766 can be set to a first value, such as a logic-1 value, to cause the data input 762 and, thus, the functional circuit node 714 to be coupled to the output 768 of the first test circuitry 760 and, thus, to the SI input 756 of the flip-flop 704. However, the control input 766 can be set to a second value, such as a logic-0 value, to cause the second data input 764 and, thus, the output 770 of the flip-flop 702 to be coupled to the output 768 of the first test circuitry 760 and, thus, to the SI input 756 of the flip-flop 704.

With this in mind, the second test circuitry 772 is configured to output the first value, such as the logic-1 value, at its first output 774 during a capture period of a scan test, which sets the control input 766 of the first test circuitry 760 to the first value, such as the logic-1 value. That causes the data input 762 and, thus, the functional circuit node 714 to be coupled to the output 768 of the first test circuitry 760 and, thus, to the SI input 756 of the flip-flop 704 during the capture period of the scan test. However, the second test circuitry 772 is also configured to output the second value, such as the logic-0 value, at its first output 774 during a shift period of the scan test, which sets the control input 766 of the first test circuitry 760 to the second value, such as the logic-0 value. That causes the data input 764 and, thus, the output 770 of the flip-flop 702 to be coupled to the output 768 of the first test circuitry 760 and, thus, to the SI input 756 of the flip-flop 704 during the shift period of the scan test. In this manner, the second test circuitry 772 is configured to cause the first test circuitry 760 to output the observed value from the functional circuit node 714 to the SI input 756 of the flip-flop 704 during a capture period of a scan test, and to cause the first test circuitry 760 to output a test pattern value received by the flip-flop 702 to the SI input 756 of the flip-flop 704 during a shift period of the scan test.

In the illustrated example, the second test circuitry 772 is also configured to output the first value, such as the logic-1 value, at its second output 776 during the scan test. Because the second output 776 of the second test circuitry 772 is coupled to the SE input 758 of the flip-flop 704, this causes the flip-flop 704 to couple its SI input 756 to the output 734 of the flip-flop 704 during the scan test. As a result, the second test circuitry 772 causes the observed value from the functional circuit node 714 to be output at the output 734 of the flip-flop 704 during a capture period of a scan test, and causes the test pattern value received by the flip-flop 702 to be output at the output 734 of the flip-flop 704 during a shift period of the scan test. Furthermore, the second test circuitry 772 is also configured to output the second value, such as the logic-0 value, at its second output 776 during normal operation of the device 710 (e.g., such as when the scan test is disabled). Because the second output 776 of the second test circuitry 772 is coupled to the SE input 758 of the flip-flop 704, this causes the flip-flop 704 to couple its primary input 732 to the output 734 of the flip-flop 704. As a result, during normal operation of the device 710 (e.g., such as when the scan test is disabled) an output value received from the functional circuit node 716 is output at the output 734 of the flip-flop 704

In the illustrated example, to implement such operation, the second test circuitry 772 includes an example OR gate 778, an example flip-flop 780 (labeled in FIG. 7 as a decoder (DCDR) flop), and an example inverter 782. The OR gate 778 accepts as input an example control signal 784 labeled “SE” in the illustrated example. The value of the control signal 784 is set (e.g., by an ATPG) to a logic-1 value during a shift period of a scan test of the device 710, and is set to a logic-0 value during a capture period of the scan test of the device 710. The inverter 782 is coupled to the first output 774 of the second test circuitry 772. Thus, inverter 782 provides an inverted version of the control signal 784 at the first output 774 of the second test circuitry 772, which is set to a logic-0 value during a shift period of a scan test of the device 710, and is set to a logic-1 value during a capture period of the scan test of the device 710. The flip-flop 780 of the second test circuitry 772 is arranged in a feedback configuration and is configured to output a logic-1 value during a scan test of the device 710, and to output a logic-0 value during normal operation of the device 710. This causes the second output 776 of the second test circuitry 772, which is coupled to the OR gate 778, to output a logic-1 value during a scan test of the device 710, and to output a logic-0 value during normal operation of the device 710, as described above.

In the illustrated example third circuit architecture 700, the flip-flop 704 is repurposed to implement the control TP for the functional circuit node 718 as follows. The device 710 includes third example test circuitry 786 that has a first data input 788, a control input 790, and an output 792. For example, the third test circuitry 786 can be implemented by a multiplexer or similar circuit. In the illustrated example, the first data input 788 of the third test circuitry 786 is coupled to the output 734 of the flip-flop 704, and the functional circuit node 718 is coupled to the output 792 of the third test circuitry 786. The third test circuitry 660 also includes a second data input 794 that is coupled with the functional circuit node 720. The third test circuitry 786 is configured to couple either the data input 788 or the data input 794 to the output 792 based on the control input 790 of the third test circuitry 786. For example, the control input 790 can be set to a second value, such as a logic-0 value, to cause the data input 794 and, thus, the functional circuit node 720 to be coupled to the functional circuit node 718 during normal operation of the device 710. However, the control input 790 can be set to a first value, such as a logic-1 value, to cause the data input 788 and, thus, the output 734 of the flip-flop 704 to be coupled to the functional circuit node 718 during a scan test of the device 710.

In the illustrated example of FIG. 7, the control input 790 of the third test circuitry 660 is coupled to the second output 776 of the second test circuitry 772. As described above, the second output 776 of the second test circuitry 772 outputs a logic-1 value during a scan test of the device 710, and outputs a logic-0 value during normal operation of the device 710. As a result, the third test circuitry 786 causes the output 734 of the flip-flop 704 to be coupled to the functional circuit node 718 during a scan test of the device 710 (e.g., when the scan test is enabled), and the third test circuitry 786 causes the functional circuit node 720 to be coupled to the functional circuit node 718 during normal operation of the device 710 (e.g., when the scan test is disabled). Furthermore, during a shift period of a scan test of the device 710, the second test circuitry 772 causes the first test circuitry 760 to provide the test pattern value at the output 770 of the flip-flop 702 to the output 734 of the flip-flop 704, which is coupled to the functional circuit node 718. In this way, the output 734 of the flip-flop 704 is able to control the functional circuit node 718 during the shift period of the scan test.

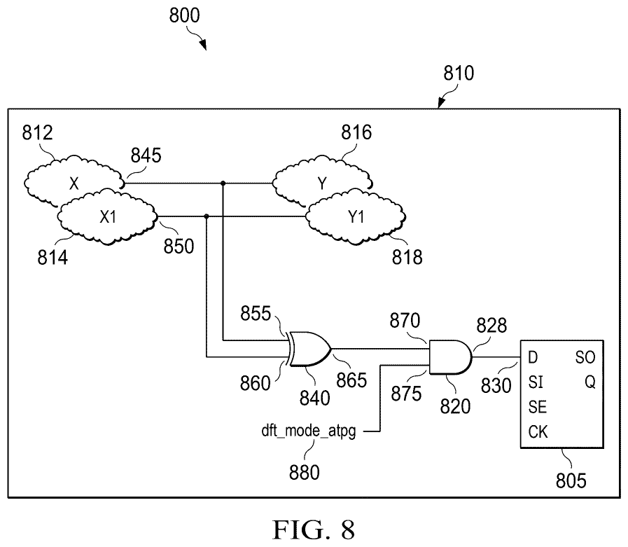

A block diagram illustrating a fourth example circuit architecture 800 to share an example flip-flop 805 used to implement an observe test point for scan testing of a device 810 is illustrated in FIG. 8. The device 810 can be any type of device, such as an SoC device, an IC, a semiconductor device, an optical device, a compute device, a memory device, etc. In the illustrated example of FIG. 8, the device 810 includes example functional circuit nodes 812, 814, 816 and 818 configured to implement functionality in the device 810. The functional circuit nodes 812, 814, 816 and 818 can be any numbers and/or types of circuits or circuitry, such as digital circuitry, analog circuitry, circuit blocks, IP blocks, accelerators, etc. For example, the functional circuit nodes 812, 814, 816 and 818 can range from discrete digital logic gates to more complete circuitry, such as one or more memories, microcontrollers, CPUs, GPUs, etc.

In the illustrated example of FIG. 8, the flip-flop 805 can be an additional flip-flop added to the device 810 to provide an observe TP, such as in the example of FIG. 2, or a re-used flip-flop already included in the device 810 to implement functionality in the device 810, such as in the examples of FIGS. 5-7. In the illustrated example of FIG. 8, the functional circuit nodes 812 and 814 are to be observed during a scan test of the device 810. To support such scan testing, the fourth circuit architecture 800 uses the flip-flop 805 to implement a single observe TP to observe the functional circuit nodes 812 and 814.

In the illustrated example fourth circuit architecture 800, the flip-flop 805 is used to implement the observe TP as follows. The device 810 includes an example AND gate 820 that has an output 825 coupled to an input 830 of the flip-flop 805. The device 810 also includes example circuitry 840 to combine respective observe outputs 845 and 850 of the functional circuit nodes 812 and 814. The circuitry 840 has an input 855 coupled to the output 845 of the functional circuit node 812 and an input 860 coupled to the output 850 of the functional circuit node 814. The circuitry 840 also has an output 865 coupled to an input 870 of the AND gate 820. In the fourth circuit architecture 800, the circuitry 840 is configured to detect a particular combination of values output from the functional circuit nodes 812 and 814 during a scan test of the device 810 and to output a first value, such as a logic-1 value, if the values output from the functional circuit nodes 812 and 814 matches that combination. For example, the circuitry 840 can be implemented by an example exclusive-OR (XOR) gate to detect a particular output combination in which one of the functional circuit nodes 812 and 814 outputs a logic-1 value during the scan test, but both functional circuit nodes 812 and 814 do not output logic-1 values at the same time. In some examples, the circuitry 840 is implemented with a multiplexer or similar circuitry to select which of the observe outputs 845 and 850 is to be coupled to the AND gate 820, thereby selecting which of the functional circuit nodes 812 and 814 is to be observed at a particular time during the scan test.

In the example fourth circuit architecture 800, the AND gate also has an input 875 that accepts an example control signal 880 labeled “dft_mode_atpg” in the illustrated example. The value of the control signal 880 is set to a logic-1 value during a scan test of the device 810, and is set to a logic-0 value during normal operation of the device 810. Thus, during a scan-test of the device 810, the AND gate 820 outputs a first value, such as a logic-1 value, at its output if the particular combination of values output from the functional circuit nodes 812 and 814 is detected. The input 830 of the flip-flop 805 captures that result from the AND gate 820, thereby implementing an observe TP for the combination of functional circuit nodes 812 and 814.

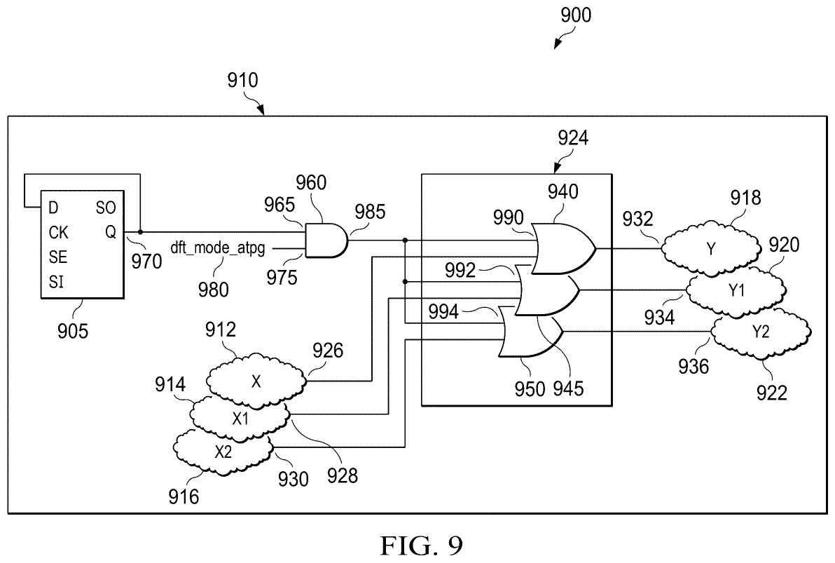

A block diagram illustrating a fifth example circuit architecture 900 to share a flip-flop 905 used to implement a control test point for scan testing of a device 910 is illustrated in FIG. 9. The device 910 can be any type of device, such as an SoC device, an IC, a semiconductor device, an optical device, a compute device, a memory device, etc. In the illustrated example of FIG. 9, the device 910 includes example functional circuit nodes 912, 914, 916, 918, 920 and 922 configured to implement functionality in the device 910. The functional circuit nodes 912, 914, 916, 918, 920 and 922 can be any numbers and/or types of circuits or circuitry, such as digital circuitry, analog circuitry, circuit blocks, IP blocks, accelerators, etc. For example, the functional circuit nodes 912, 914, 916, 918, 920 and 922 can range from discrete digital logic gates to more complete circuitry, such as one or more memories, microcontrollers, CPUs, GPUs, etc.

In the illustrated example of FIG. 9, the flip-flop 905 can be an additional flip-flop added to the device 910 to provide a control TP, such as in the examples of FIGS. 3 and 4, or a re-used flip-flop already included in the device 910 to implement functionality in the device 910, such as in the examples of FIGS. 5-7. In the illustrated example of FIG. 9, the functional circuit nodes 918, 920 and 922 are to be controlled during a scan test of the device 810. To support such scan testing, the fifth circuit architecture 900 uses the flip-flop 905 to implement a single control TP to control the functional circuit nodes 918, 920 and 922.

In the illustrated example fifth circuit architecture 900, the flip-flop 905 is used to implement the control TP as follows. During normal operation of the device 910, the functional circuit node 912 is coupled to the functional circuit node 918, the functional circuit node 914 is coupled to the functional circuit node 920, and the functional circuit node 916 is coupled to the functional circuit node 922. In the fifth circuit architecture 900, example circuitry 924 is interposed between the functional circuit nodes 912, 914 and 916 and the functional circuit nodes 918, 920 and 922. The example circuitry 924 causes respective outputs 926, 928 and 930 of the functional circuit nodes 912, 914 and 916 to be coupled to respective inputs 932, 934 and 936 of the functional circuit nodes 918, 920 and 922 during normal operation of the device 910. However, during a scan test of the device 910, the circuitry 924 causes the respective inputs 932, 934 and 936 of the functional circuit nodes 918, 920 and 922 to be controlled based on a logic value provided by the flip-flop 905.

For example, and as shown in FIG. 9, the circuitry 924 can be implemented by an example OR gate 940 that is interposed between the functional circuit node 912 and the functional circuit node 918, an example OR gate 945 that is interposed between the functional circuit node 914 and the functional circuit node 920, and an example OR gate 950 that is interposed between the functional circuit node 916 and the functional circuit node 922, which is similar to the example of FIG. 3 to support controlling the functional circuit nodes 918, 920 and 922 with a logic-1 value during a scan test. In some examples, the circuitry 924 can be implemented by combinations of inverters and NOR gates interposed between the functional circuit nodes 912-916 and 918-922 in a manner similar to the example of FIG. 4 to support controlling the functional circuit nodes 918, 920 and 922 with a logic-0 value during a scan test. In some examples, the circuitry 924 is implemented by one or more multiplexers that selectively couple the outputs 926, 928 and 930 of the functional circuit nodes 912, 914 and 916, or a control logic value, to the inputs 932, 934 and 936 of the functional circuit nodes 918, 920 and 922.

In the example fifth circuit architecture 900, the device 910 includes an example AND gate 960 that has an input 965 coupled to an output 970 of the flip-flop 905. The flip-flop 905 is arranged in a feedback configuration and can be configured to output a logic-1 value or a logic-0 value during a scan test of the device 910. In the fifth circuit architecture 900, the AND gate also has an input 975 that accepts an example control signal 980 labeled “dft_mode_atpg” in the illustrated example. The value of the control signal 980 is set to a logic-1 value during a scan test of the device 910, and is set to a logic-0 value during normal operation of the device 910. The AND gate 960 of the illustrated example further includes an example output 985 coupled to the input of the circuitry 924 (e.g., to respective inputs 990, 992 and 994 of the OR gates 940, 945 and 950 in the illustrated example). Thus, during a scan-test of the device 910, the AND gate 960 outputs the control value from the flip-flop 905 during the scan test, which is provided to the inputs 932, 934 and 936 of the functional circuit nodes 918, 920 and 922 via the circuitry 924, thereby implementing a control TP for the combination of functional circuit nodes 918, 920 and 922.

The circuit architectures described above are examples and the TPI techniques disclosed herein are not limited thereto. On the contrary, the TPI techniques disclosed can be used to support scan testing of devices that contain one or more flip-flops, or similar types of circuitry.

Examples described herein include one or more flip-flops. The flip-flops described herein can be implemented by any numbers and/or types of flip-flop circuits, latch circuits, memory circuits, etc. For example, the flip-flops described herein may include D flip-flops, J-K flip-flops, R-S flip-flops, T flip-flops, etc.

Examples described herein included one or more functional circuit nodes. The functional circuit nodes are not limited to the examples described above. For example, the functional circuit nodes can correspond to any processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs, etc., or any combinations thereof.

Examples described herein reference logic-1 values and logic-0 values. Logic-1 values and logic-0 values can be any values that represent a logic-1 and a logic-0, respectively. For example, the logic-1 values and the logic-0 values can be respect voltage values, current values, intensity values, resistance values, capacitance values, inductance values, or ranges and/or combinations of such values. For example, a logic-1 value can correspond to a voltage value greater than or equal to a first threshold voltage value, such as 1.8 volts (V), 3.3 V, 5 V, etc., and a logic-0 value can correspond to a voltage value less than that first threshold voltage value. In some examples, a logic-0 value can correspond to a voltage value less than, or less then or equal to, a second threshold voltage value, such as 0.5 V, 0.2 V, etc.

Through the re-use of existing functional flip-flops already present in a device's circuit design, examples disclosed herein reduce and may even avoid additional active/leakage power consumption associated with scan testing of the device. Different techniques for clocking the flip-flops during scan testing of the device can also be employed to reduce the power consumption associated with scan testing of the device. Examples of such techniques are described in Indian Provisional Patent Application No. 202441058892, filed Aug. 2, 2024, which is incorporated herein by reference in its entirety.

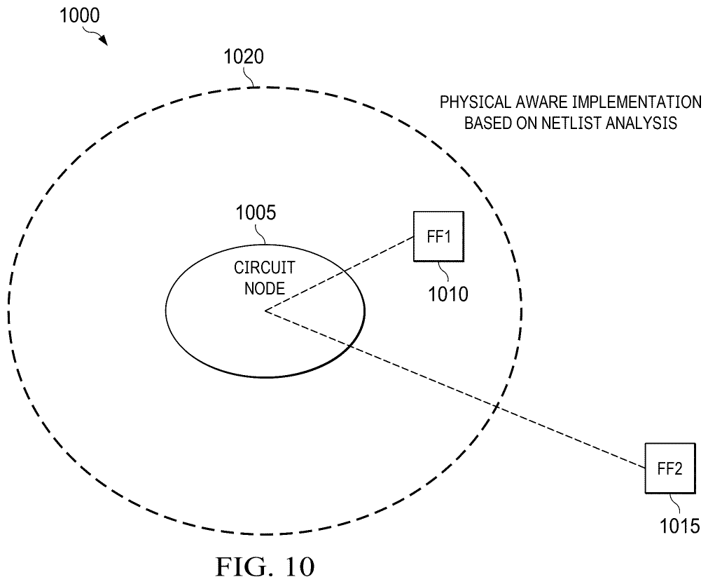

An example procedure 1000 to select a functional flip-flop of a device to be repurposed for scan testing of the device is illustrated in FIG. 10. In the example procedure 1000, an example functional circuit node 1005 is to be observed and/or controlled during a scan test of the device. The functional circuit node 1005 can be any numbers and/or types of circuits or circuitry, such as digital circuitry, analog circuitry, circuit blocks, IP blocks, accelerators, etc. For example, the functional circuit node 1005 can range from discrete digital logic gates to more complete circuitry, such as one or more memories, microcontrollers, CPUs, GPUs, etc.

The procedure 1000 of the illustrated example analyzes a netlist representative of the device to identify flip-flops that can be reused to implement observe and/or control TPs for the functional circuit node 1005. In the illustrated example, the procedure 1000 identifies example flip-flops 1010 and 1015 as candidate flip-flops to be reused to implement observe and/or control TPs for the functional circuit node 1005. The procedure 1000 also employs an example distance threshold 1020 to select one or more of the candidate flip-flops within the distance threshold 1020 of the functional circuit node 1005 to be reused to implement observe and/or control TPs for the functional circuit node 1005. In the illustrated example, the procedure 1000 selects the flip-flop 1010 because it is located within the threshold distance 1020 of the functional circuit node 1005. In this manner, the procedure 1000 implements a physically aware flip-flop selection procedure to case routing congestion and optimize area by selecting candidate TP flip-flops closer to the functional circuit node to be controlled and/or observed.

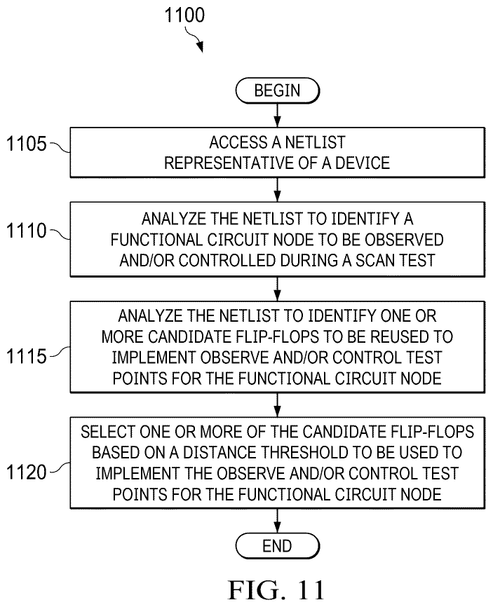

FIG. 11 is a flowchart representative of example machine-readable instructions and/or example operations 1100 that may be at least one of executed, instantiated, or performed by programmable circuitry to implement one of more software tools to perform the example flip-flop selection procedure 1000 of FIG. 10. The example machine-readable instructions and/or the example operations 1100 of FIG. 11 begin at block 1105, at which an example software tool accesses a netlist representative of a device. At block 1110, the software tool analyzes the netlist to identify a functional circuit node, such as the functional circuit node 1005, to be observed and/or controlled during a scan test of the device. At block 1115, the software tool analyzes the netlist to identify candidate flip-flops, such as the flip-flops 1010 and 1015, to be reused to implement observe and/or control TPs for the functional circuit node identified at block 1110. At block 1120, the software tool selects one or more of the candidate flip flops based on a distance threshold. For example, the software tool selects the flip-flop 1010 because it is within the distance threshold 1020 of the functional circuit node 1005. The example machine-readable instructions and/or the example operations 1100 then end.

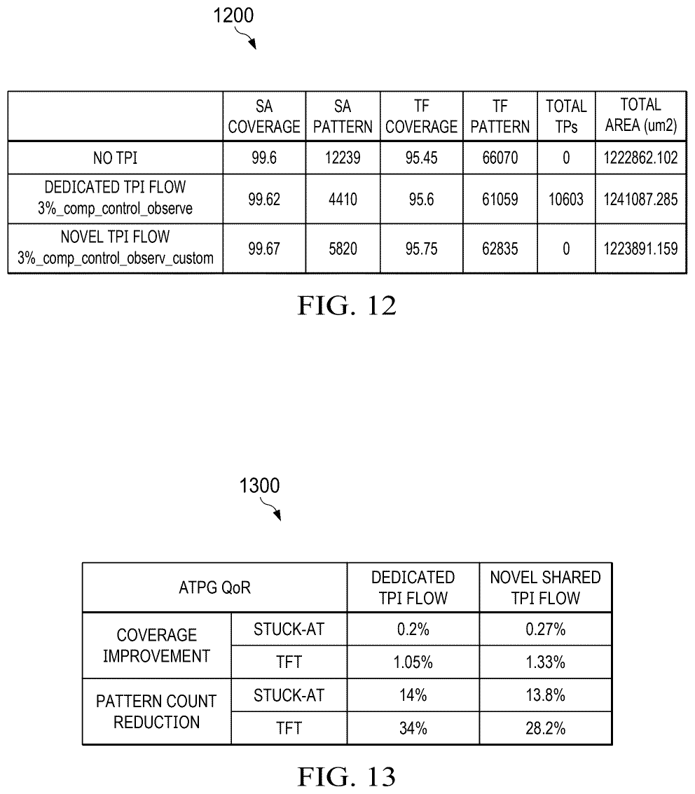

FIGS. 12-13 illustrate example performance results 1200 and 1300 for the example TPI techniques based on flip-flop repurposing described herein. The performance results 1200 and 1300 demonstrate reductions of DFT area overhead and test coverage improvements achievable by the example TPI techniques based on flip-flop repurposing described herein. For example, the performance results 1200 demonstrate that the example TPI techniques based on flip-flop repurposing described herein can achieve an area savings as a sub-chip level of approximately 17,200 μm² relative to techniques that add dedicated scan testing flip-flops to the sub-chip design This can translate to an overall savings as an SoC level of approximately 200,000 μm², which is equivalent to approximately 256 kilobytes of additional static random access memory (SRAM) that can be installed in the device.

Furthermore, the performance results 1200 and 1300 demonstrate that the example TPI techniques based on flip-flop repurposing described herein can improve device quality scan coverage by approximately 0.07% for stuck-at (SA) testing and approximately 0.3% for transition delay fault (TDF) testing compared to no TPI methodology on representative sub-chips. The performance results 1200 and 1300 also demonstrate that the example TPI techniques based on flip-flop repurposing described herein can reduce ATPG pattern count by approximately 52% for SA testing and approximately 5% for TDF testing on representative sub-chips, which contributes to a reduction of test time as compared to no TPI.

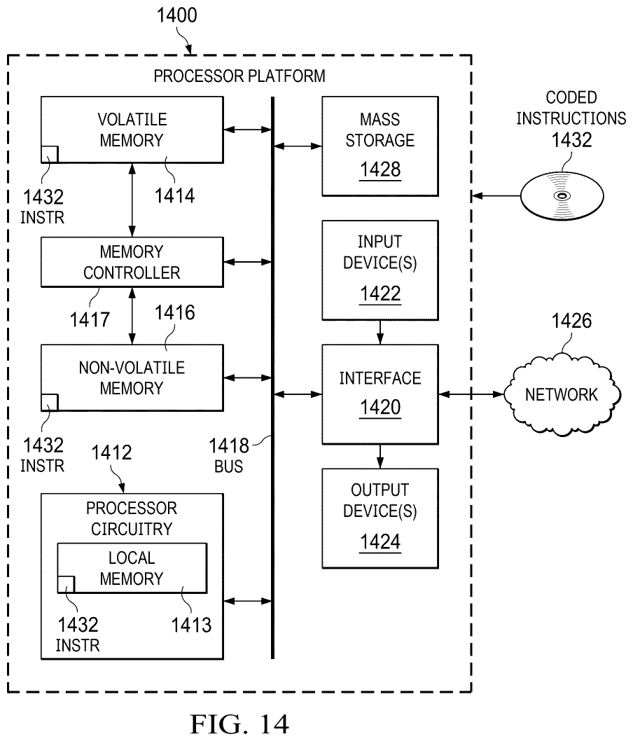

FIG. 14 is a block diagram of an example programmable circuitry platform 1400 structured to one or a combination of execute or instantiate one or more of the example machine-readable instructions or the example operations of FIG. 11 to implement the [ER-Apparatus] of FIG. [ER-Diagram]. The programmable circuitry platform 1400 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing or electronic device.

The programmable circuitry platform 1400 of the illustrated example includes programmable circuitry 1412. The programmable circuitry 1412 of the illustrated example is hardware. For example, the programmable circuitry 1412 can be implemented by one or more integrated circuits, logic circuits, FPGAs, microprocessors, CPUs, GPUs, DSPs, or microcontrollers from any desired family or manufacturer. The programmable circuitry 1412 may be implemented by one or more semiconductor based (e.g., silicon based) devices.

The programmable circuitry 1412 of the illustrated example includes a local memory 1413 (e.g., a cache, registers, etc.). The programmable circuitry 1412 of the illustrated example is in communication with main memory 1414, 1416, which includes a volatile memory 1414 and a non-volatile memory 1416, by a bus 1418. The volatile memory 1414 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 1416 may be implemented by one or a combination of flash memory or any other desired type of memory device. Access to the main memory 1414, 1416 of the illustrated example is controlled by a memory controller 1417. In some examples, the memory controller 1417 may be implemented by one or more integrated circuits, logic circuits, microcontrollers from any desired family or manufacturer, or any other type of circuitry to manage the flow of data going to and from the main memory 1414, 1416.

The programmable circuitry platform 1400 of the illustrated example also includes interface circuitry 1420. The interface circuitry 1420 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1422 are connected to the interface circuitry 1420. The input device(s) 1422 permit(s) a user (e.g., a human user, a machine user, etc.) to enter one of or a combination of data or commands into the programmable circuitry 1412. The input device(s) 1422 can be implemented by, for example, one of or a combination of an audio sensor, a microphone, a camera (still or video), a keyboard, a button, a mouse, a touchscreen, a trackpad, a trackball, an isopoint device, or a voice recognition system.

One or more output devices 1424 are also connected to the interface circuitry 1420 of the illustrated example. The output device(s) 1424 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 1420 of the illustrated example, thus, includes one of or a combination of a graphics driver card, a graphics driver chip, or graphics processor circuitry such as a GPU.

The interface circuitry 1420 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 1426. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1400 of the illustrated example also includes one or more mass storage discs or devices 1428 to store one or more of firmware, software, or data. Examples of such mass storage discs or devices 1428 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 1432, which may be implemented by the machine-readable instructions of FIG. 11, may be stored in one of or a combination of the mass storage device 1428, in the volatile memory 1414, in the non-volatile memory 1416, or on at least one non-transitory computer readable storage medium such as a CD or DVD which may be removable.

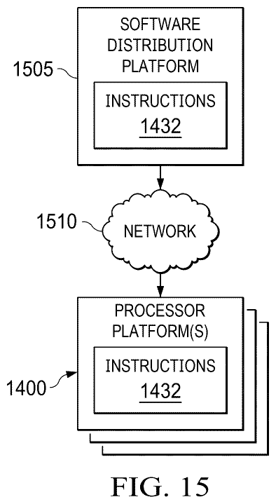

A block diagram illustrating an example software distribution platform 1505 to distribute software such as the example machine-readable instructions 1432 of FIG. 14 to other hardware devices (e.g., one or more hardware devices owned or operated by third parties from the owner or operator of the software distribution platform) is illustrated in FIG. 15. The example software distribution platform 1505 may be implemented by any computer server, data facility, cloud service, etc., capable of storing and transmitting software to other computing devices. The third parties may be customers of the entity at least one of owning or operating the software distribution platform 1505. For example, the entity that at least one of owns or operates the software distribution platform 1505 may be at least one of a developer, a seller, or a licensor of software such as the example machine-readable instructions 1432 of FIG. 14. The third parties may be consumers, users, retailers, OEMs, etc., who one of or a combination of purchase or license the software for at least one of use, re-sale, or sub-licensing. In the illustrated example, the software distribution platform 1505 includes one or more servers and one or more storage devices. The storage devices store the machine-readable instructions 1432, which may correspond to the example machine-readable instructions of FIGS. 11, as described above. The one or more servers of the example software distribution platform 1505 are in communication with an example network 1510, which may correspond to any one or more of the Internet or any of the example networks described above. In some examples, the one or more servers are responsive to requests to transmit the software to a requesting party as part of a commercial transaction. Payment for at least one of the delivery, sale, or license of the software may be handled by the one or more servers of at least one of the software distribution platform or by a third party payment entity. The servers enable one or more purchasers or licensors to download the machine-readable instructions 1432 from the software distribution platform 1505. For example, the software, which may correspond to the example machine-readable instructions of FIG. 11, may be downloaded to the example programmable circuitry platform 1400, which is to execute the machine-readable instructions 1432 to implement the software tool(s) described herein. In some examples, one or more servers of the software distribution platform 1505 periodically at least one of offer, transmit, or force updates to the software (e.g., the example machine-readable instructions 1432 of FIG. 14) to ensure improvements, patches, updates, etc., are distributed and applied to the software at the end user devices. Although referred to as software above, the distributed “software” could alternatively be firmware.

Flowchart(s) representative of example machine-readable instructions, which may be executed by programmable circuitry to at least one of implement or instantiate the software tool(s) described herein to perform flip-flop selection or representative of example operations which may be performed by programmable circuitry to at least one of implement or instantiate the software tool(s) described herein to perform flip-flop selection, are shown in FIG. 11. The machine-readable instructions may be one or more executable programs or portion(s) of one or more executable programs for execution by programmable circuitry such as the programmable circuitry 1412 shown in the example processor platform 1400 discussed below in connection with FIG. 14. In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIG. 11, many other methods of implementing the example software tool(s) described herein may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). For example, the programmable circuitry may be one of or a combination of a CPU or an FPGA located in the same package (e.g., the same integrated circuit (IC) package or in two or more separate housings), one or more processors in a single machine, multiple processors distributed across multiple servers of a server rack, multiple processors distributed across one or more server racks, etc., or any combination(s) thereof.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, wherein the parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 11 may be implemented using executable instructions (e.g., computer readable and/or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing at least one of a semiconductor device (e.g., a transistor), a semiconductor die containing a semiconductor device, or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. Semiconductor devices are often used in orientation different than their orientation during fabrication. Thus, when referring to one of or a combination of a semiconductor device (e.g., a transistor), a semiconductor die containing a semiconductor device, or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

From the foregoing, it will be appreciated that example systems, apparatus, articles of manufacture, and methods have been described that implement TPI techniques that repurpose flip-flops for circuit testing based on scan chains. Described systems, apparatus, articles of manufacture, and methods improve the efficiency of a computing device by providing TPI solutions that reduce or even eliminate the use of dedicated flip-flops to implement TPs for observing and/or controlling functional circuit nodes during scan testing of the device. As a result, TPI solutions described herein can yield a substantial reduction in the DFT circuit overhead in the device while still reaping the benefits of TPs. TPI solutions described herein also result in scan coverage improvement, pattern count reduction, reduced test time, and reduced active/leakage power consumption relative to other TPI techniques that add dedicated flip-flops to support DFT. Furthermore, TPI solutions described herein enable the scan coverage improvement for production test as well as local built-in self-test (LBIST) used for in-field testing. These improvements can be useful for complying with and exceeding safety standards in automotive (e.g., ASIL), industrial, aviation, autonomous vehicles, etc.

Further examples and combinations thereof include the following. Example 1 includes a device comprising first functional circuitry, second functional circuitry, a shift register coupled to the first functional circuitry, wherein the shift register includes a flip-flop, the flip-flop including a scan-in input coupled to the second functional circuitry, a scan-enable input, and an output, and first test circuitry coupled to the scan-enable input and configured to cause the flip-flop to output a first value received by the flip-flop at the scan-in input from the second functional circuitry.

Example 2 includes the device of example 1, wherein the flip-flop includes a primary input, and wherein the first test circuitry is configured to cause the flip-flop to output, during a capture period of a scan test, the first value received by the flip-flop at the scan-in input from the second functional circuitry, and cause the flip-flop to output, during a shift period of the scan test, a second value received by the flip-flop at the primary input.

Example 3 includes the device of example 2, wherein the first test circuitry is configured to output a first logic value to the scan-enable input to define the capture period, and output a second logic value to the scan-enable input to define the shift period.

Example 4 includes the device of example 2 or example 3, further comprising scan chain circuitry coupled to the primary input of the flip-flop and configured to output the second value during the shift period.

Example 5 includes the device of example 1, further comprising third functional circuitry, and second test circuitry coupled to the output of the flip-flop and coupled to the third functional circuitry.

Example 6 includes the device of example 5, wherein the flip-flop includes a primary input, wherein the first test circuitry is configured to cause the flip-flop to output, during a capture period of a scan test, the first value received by the flip-flop at the scan-in input from the second functional circuitry, and cause the flip-flop to output, during a shift period of the scan test, a second value received by the flip-flop at the primary input, and wherein the second test circuitry is configured to receive the second value from the flip-flop, and output the second value to the third functional circuitry.

Example 7 includes the device of example 1, further comprising third functional circuitry, wherein the flip-flop is a first flip-flop, and the shift register includes a second flip-flop, the second flip-flop including a primary input coupled to the output of the first flip-flop, a scan-in input coupled to the third functional circuitry, a scan-enable input coupled to the first test circuitry, and an output.

Example 8 includes the device of example 7, wherein the first test circuitry is configured to cause the first flip-flop to output, during a capture period of a scan test, the first value received at the scan-in input of the first flip-flop from the second functional circuitry, cause the first flip-flop to output, during a shift period of the scan test, a second value received at the primary input of the first flip-flop, cause the second flip-flop to output, during the shift period of the scan test, the second value received at the primary input of the second flip-flop from the output of the first flip-flop, and. cause the second flip-flop to output, during the capture period of the scan test, a third value received at the scan-in input of the second flip-flop from the third functional circuitry.

Example 9 includes a device comprising a flip-flop including a primary input, a scan-in input, and a scan-enable input, first functional circuitry coupled to the primary input of the flip-flop, first test circuitry coupled to the scan-in input of the flip-flop, second functional circuitry coupled to the first test circuitry, and second test circuitry coupled to the first test circuitry and coupled to the scan-enable input of the flip-flop, wherein the second test circuitry is configured to cause the first test circuitry to output a first value to the scan-in input of the flip-flop, the first value received from the second functional circuit.

Example 10 includes the device of example 9, wherein the flip-flop is a first flip-flop, wherein the device further comprises a second flip-flop coupled to the first test circuitry, and wherein the second test circuitry is configured to cause the first test circuitry to output the first value to the scan-in input of the first flip-flop during a capture period of a scan test, and output a second value to the scan-in input of the first flip-flop during a shift period of the scan test, the second value received from the second flip-flop.

Example 11 includes the device of example 10, wherein the second test circuitry is configured to cause the first flip-flop to output the first value during the capture period of the scan test, and output the second value during the shift period of the scan test.

Example 12 includes the device of example 11, wherein the second test circuitry is configured to cause the first flip-flop to output a third value received from the first functional circuitry when the scan test is disabled.

Example 13 includes the device of example 9, further comprising third functional circuitry, fourth functional circuitry, and third test circuitry coupled to the flip-flop, coupled to the third functional circuitry, and coupled to the fourth functional circuitry.

Example 14 includes the device of example 13, wherein the third test circuitry is coupled to the second test circuitry, and wherein the second test circuitry is configured to cause the third test circuitry to couple the flip-flop to the third functional circuitry when a scan test is enabled, and couple the fourth functional circuitry to the third functional circuitry when the scan test is disabled.

Example 15 includes a device comprising a flip-flop including a primary input, a scan-in input, a scan-enable input, and an output, first functional circuitry coupled to the primary input of the flip-flop, first test circuitry including a first data input, a control input, and an output, wherein the first data input of the first test circuitry is coupled to the output of the flip-flop, second functional circuitry coupled to the output of the first test circuitry, and second test circuitry coupled to the control input of the first test circuitry.

Example 16 includes the device of example 15, wherein the first test circuitry includes a second data input, and further including third functional circuitry coupled to the second data input of the first test circuitry.

Example 17 includes the device of example 16, wherein the second test circuitry is to cause the first test circuitry to couple the output of the flip-flop to the second functional circuitry when a scan test is enabled, and couple the third functional circuitry to the second functional circuitry when the scan test is disabled.

Example 18 includes the device of any one of examples 15 to 17, wherein the output of the flip-flop is a scan-out output of the flip-flop.

Example 19 includes the device of example 15, wherein the flip-flop is a first flip-flop, and further including a second flip-flop including a primary input, a scan-in input, a scan-enable input, and an output, third test circuitry including a first data input, a second data input, a control input, and an output, the output of the third test circuitry coupled to the primary input of the second flip-flop, third functional circuitry coupled to the first data input of the third test circuitry, and fourth functional circuitry coupled to the second data input of the third test circuitry, wherein the second test circuitry is coupled to the control input of the third test circuitry.

Example 20 includes the device of example 19, wherein the second test circuitry is configured to cause the third test circuitry to couple the third functional circuitry to the primary input of the second flip-flop when a scan test is enabled, and couple the fourth functional circuitry to the primary input of the second flip-flop when the scan test is disabled.

The following claims are hereby incorporated into this Detailed Description by this reference. Although certain example systems, apparatus, articles of manufacture, and methods have been described herein, the scope of coverage of this patent is not limited thereto. On the contrary, this patent covers all systems, apparatus, articles of manufacture, and methods fairly falling within the scope of the claims of this patent.

What is claimed is:

1. A device comprising:
first functional circuitry;
second functional circuitry;
a shift register coupled to the first functional circuitry, wherein the shift register includes a flip-flop, the flip-flop including:
a scan-in input coupled to the second functional circuitry;
a scan-enable input; and
an output; and
first test circuitry coupled to the scan-enable input and configured to cause the flip-flop to output a first value received by the flip-flop at the scan-in input from the second functional circuitry.

2. The device of claim 1,
wherein the flip-flop includes a primary input, and
wherein the first test circuitry is configured to:
cause the flip-flop to output, during a capture period of a scan test, the first value received by the flip-flop at the scan-in input from the second functional circuitry; and
cause the flip-flop to output, during a shift period of the scan test, a second value received by the flip-flop at the primary input.

3. The device of claim 2, wherein the first test circuitry is configured to:
output a first logic value to the scan-enable input to define the capture period; and
output a second logic value to the scan-enable input to define the shift period.

4. The device of claim 2, further comprising scan chain circuitry coupled to the primary input of the flip-flop and configured to output the second value during the shift period.

5. The device of claim 1, further comprising:
third functional circuitry; and
second test circuitry coupled to the output of the flip-flop and coupled to the third functional circuitry.

6. The device of claim 5,
wherein the flip-flop includes a primary input,
wherein the first test circuitry is configured to:
cause the flip-flop to output, during a capture period of a scan test, the first value received by the flip-flop at the scan-in input from the second functional circuitry; and
cause the flip-flop to output, during a shift period of the scan test, a second value received by the flip-flop at the primary input, and
wherein the second test circuitry is configured to:
receive the second value from the flip-flop; and
output the second value to the third functional circuitry.

7. The device of claim 1, further comprising third functional circuitry, wherein the flip-flop is a first flip-flop, and the shift register includes a second flip-flop, the second flip-flop including:
a primary input coupled to the output of the first flip-flop;
a scan-in input coupled to the third functional circuitry;
a scan-enable input coupled to the first test circuitry; and
an output.

8. The device of claim 7, wherein the first test circuitry is configured to:
cause the first flip-flop to output, during a capture period of a scan test, the first value received at the scan-in input of the first flip-flop from the second functional circuitry;
cause the first flip-flop to output, during a shift period of the scan test, a second value received at the primary input of the first flip-flop;
cause the second flip-flop to output, during the shift period of the scan test, the second value received at the primary input of the second flip-flop from the output of the first flip-flop; and.
cause the second flip-flop to output, during the capture period of the scan test, a third value received at the scan-in input of the second flip-flop from the third functional circuitry.

9. A device comprising:
a flip-flop including a primary input, a scan-in input, and a scan-enable input;
first functional circuitry coupled to the primary input of the flip-flop;
first test circuitry coupled to the scan-in input of the flip-flop;
second functional circuitry coupled to the first test circuitry; and
second test circuitry coupled to the first test circuitry and coupled to the scan-enable input of the flip-flop,
wherein the second test circuitry is configured to cause the first test circuitry to output a first value to the scan-in input of the flip-flop, the first value received from the second functional circuit.

10. The device of claim 9, wherein the flip-flop is a first flip-flop, wherein the device further comprises a second flip-flop coupled to the first test circuitry, and wherein the second test circuitry is configured to cause the first test circuitry to:
output the first value to the scan-in input of the first flip-flop during a capture period of a scan test; and
output a second value to the scan-in input of the first flip-flop during a shift period of the scan test, the second value received from the second flip-flop.

11. The device of claim 10, wherein the second test circuitry is configured to cause the first flip-flop to:
output the first value during the capture period of the scan test; and
output the second value during the shift period of the scan test.

12. The device of claim 11, wherein the second test circuitry is configured to cause the first flip-flop to output a third value received from the first functional circuitry when the scan test is disabled.

13. The device of claim 9, further comprising:
third functional circuitry;
fourth functional circuitry; and
third test circuitry coupled to the flip-flop, coupled to the third functional circuitry, and coupled to the fourth functional circuitry.

14. The device of claim 13, wherein the third test circuitry is coupled to the second test circuitry, and wherein the second test circuitry is configured to cause the third test circuitry to:
couple the flip-flop to the third functional circuitry when a scan test is enabled; and
couple the fourth functional circuitry to the third functional circuitry when the scan test is disabled.

15. A device comprising:
a flip-flop including a primary input, a scan-in input, a scan-enable input, and an output;
first functional circuitry coupled to the primary input of the flip-flop;
first test circuitry including a first data input, a control input, and an output, wherein the first data input of the first test circuitry is coupled to the output of the flip-flop;
second functional circuitry coupled to the output of the first test circuitry; and
second test circuitry coupled to the control input of the first test circuitry.

16. The device of claim 15, wherein the first test circuitry includes a second data input, and further including third functional circuitry coupled to the second data input of the first test circuitry.

17. The device of claim 16, wherein the second test circuitry is to cause the first test circuitry to:
couple the output of the flip-flop to the second functional circuitry when a scan test is enabled; and
couple the third functional circuitry to the second functional circuitry when the scan test is disabled.

18. The device of claim 15, wherein the output of the flip-flop is a scan-out output of the flip-flop.

19. The device of claim 15, wherein the flip-flop is a first flip-flop, and further including:
a second flip-flop including a primary input, a scan-in input, a scan-enable input, and an output;
third test circuitry including a first data input, a second data input, a control input, and an output, the output of the third test circuitry coupled to the primary input of the second flip-flop;
third functional circuitry coupled to the first data input of the third test circuitry; and
fourth functional circuitry coupled to the second data input of the third test circuitry,
wherein the second test circuitry is coupled to the control input of the third test circuitry.

20. The device of claim 19, wherein the second test circuitry is configured to cause the third test circuitry to:
couple the third functional circuitry to the primary input of the second flip-flop when a scan test is enabled; and
couple the fourth functional circuitry to the primary input of the second flip-flop when the scan test is disabled.
